(19) United States
(12) Patent Application Publication
(10) Pub. No.: US 2025/0140601 A1
(43) Pub. Date: May 1, 2025

(54) PROCESS FOR FABRICATING A DOUBLE SEMICONDUCTOR-ON-INSULATOR STRUCTURE

(71) Applicant: Soitec, BERNIN (FR)

(72) Inventors: Carine Duret, BERNIN (FR); Ludovic Ecarnot, BERNIN (FR); Charlene Porta, BERNIN (FR)

(21) Appl. No.: 18/834,746

(22) PCT Filed: Jan. 30, 2023
(86) PCT No.: PCT/FR2023/050116

§ 371 Date: Jul. 31, 2024

(30) Foreign Application Priority Data
Jan. 31, 2022 (FR) FR2200849

(51) Int. Cl. H01L 21/762; H01L 21/324

(52) U.S. Cl. CPC H01L 21/76254; H01L 21/324

(57) ABSTRACT

A method for fabricating a double semiconductor-on-insulator structure comprising the steps of: providing a first donor substrate and a handle substrate, forming a weakened zone in the donor substrate so as to delimit a first semiconductor layer to be transferred, bonding the first donor substrate to the handle substrate, a first electrically insulating layer being at the interface, and detaching at the weakened zone, treating the surface of the first transferred semiconductor layer comprising: a rapid thermal annealing, a thermal oxidation followed by a deoxidation, a smoothing heat treatment at a temperature of above 1000° C. in a non-oxidizing atmosphere, chemical-mechanical polishing, providing a second donor substrate of a second semiconductor layer to be transferred, transferring the second semiconductor layer, a second electrically insulating layer being at the interface.

### CROSS-REFERENCE TO RELATED APPLICATIONS

This application is a national phase entry under 35 U.S.C. § 371 of International Patent Application PCT/FR2023/050116, filed Jan. 30, 2023, designating the United States of America and published as International Patent Publication WO 2023/144496 A1 on Aug. 3, 2023, which claims the benefit under Article 8 of the Patent Cooperation Treaty of French Patent Application Serial No. FR2200849, filed Jan. 31, 2022.

### TECHNICAL FIELD

The present disclosure relates to a process for fabricating a double semiconductor-on-insulator structure.

### BACKGROUND

Semiconductor-on-insulator structures are multilayer structures comprising a handle substrate, which is generally made of a semiconductor such as silicon, an electrically insulating layer arranged on the handle substrate, which is generally an oxide layer such as a silicon oxide layer, and a semiconductor layer arranged on the insulating layer, which is generally a silicon layer. Such structures are referred to as “Semiconductor-On-Insulator” structures, in particular, “Silicon-On-Insulator” (SOI) structures when the semiconductor is silicon. The oxide layer is located between the substrate and the semiconductor layer. The oxide layer is then said to be “buried,” and is called the “BOX” (for “buried oxide”). In the rest of the text, the term “SOI” will be employed to designate semiconductor-on-insulator structures generally.

In addition to SOI structures comprising one BOX layer and one semiconductor layer arranged on the BOX layer, “double SOI” structures have been produced. “Double SOI” structures comprise a handle substrate, a first oxide layer or lower buried oxide layer arranged on the handle substrate, a first semiconductor layer or lower semiconductor layer arranged on the first oxide layer, a second oxide layer or upper buried oxide layer arranged on the first semiconductor layer and a second semiconductor layer or upper semiconductor layer arranged on the second oxide layer. In this double SOI structure, the first oxide layer and the first semiconductor layer constitute the first SOI, arranged in a lower portion of the structure, while the second oxide layer and the second semiconductor layer constitute the second SOI, arranged in an upper portion of the structure.

One known process for fabricating an SOI structure is the process referred to as SMART CUT™. The SMART CUT™ process comprises implanting atomic species, such as hydrogen (H) and/or helium (He), in order to create a weakened zone within a donor substrate, bonding the donor substrate to the receiver substrate via an electrically insulating layer then detaching the donor substrate at the weakened zone so as to transfer a thin layer from the donor substrate to the receiver substrate. The donor substrate and the receiver substrate preferably take the form of semiconductor wafers of 300 mm in diameter. The electrically insulating layer may be formed on the donor substrate or on the receiver substrate.

One solution proposed for obtaining a double SOI is to implement two successive SMART CUT™ processes. During the second SMART CUT™ process, the SOI obtained following the first SMART CUT™ process is used as a second receiver substrate to which a second donor substrate is bonded via a second electrically insulating layer.

The effectiveness of the bonding during the second SMART CUT™ process is determined by the quality of the surface of the first SOI serving as receiver substrate. In particular, it depends on the roughness and on the defect density of the surface after detaching the first donor substrate along the weakened zone during the first SMART CUT™ process. Specifically, during the bonding over the course of the second SMART CUT™ process, defects and other surface irregularities cause holes to be formed between the receiver substrate and the second donor substrate within the final double SOI. The holes are more often than not detrimental to the electrical performance levels of the structure and the mechanical strength of the assembly.

Surface treatments can be implemented in order to decrease the roughness and the defect density of the surface of the first SOI after detaching the first donor substrate.

Among the surface treatments usually used are heat treatments such as rapid thermal annealing or annealing in a furnace. It is also possible to implement chemical-mechanical polishing. Finally, chemical treatments sequentially causing the surface of interest to be oxidized then deoxidized can be applied.

However, applying these techniques does not make it possible to achieve a surface quality that is sufficient to make it possible to bond a second donor substrate well to the surface over the course of a new layer transfer step.

### BRIEF SUMMARY

One aim of the present disclosure is to propose a process for fabricating a double semiconductor-on-insulator structure that guarantees the donor substrate of the second semiconductor layer is bonded well to a receiver substrate resulting from a first SMART CUT™ process.

To this end, the present disclosure proposes a process for fabricating a double semiconductor-on-insulator structure comprising the following steps:
providing a first donor substrate and a handle substrate,
forming a weakened zone in the first donor substrate so as to delimit a first semiconductor layer to be transferred,
bonding the first donor substrate to the handle substrate, a first electrically insulating layer being at the interface between the handle substrate and the first donor substrate, and detaching the first donor substrate at the weakened zone, so as to obtain a semiconductor-on-insulator structure comprising, from the rear side to the front side, the handle substrate, the first electrically insulating layer and the first transferred semiconductor layer,
treating the free surface of the first transferred semiconductor layer,
providing a second donor substrate of a second semiconductor layer to be transferred, and
transferring the second semiconductor layer to the front side of the semiconductor-on-insulator structure, a second electrically insulating layer being at the interface between the first transferred semiconductor layer and the second donor substrate, wherein treating the surface of the first transferred semiconductor layer comprises the following successive steps:
   E1: rapid thermal annealing,
   E2: a sequence including a thermal oxidation followed by a deoxidation,
   E3: a smoothing heat treatment at a temperature of above 1000° C. in a non-oxidizing atmosphere, and
   E4: chemical-mechanical polishing.

The free surface of the first semiconductor layer results from detaching the first donor substrate along the weakened zone. The process for treating the surface is optimized in order to decrease the roughness and defect density thereof. The process also makes it possible to reduce the width of the ring on the outer edge of the second receiver substrate. Jointly decreasing the defect density, the roughness, the width of the ring and the irregularity of the ring (a phenomenon known by the term “jagged edge”) on the outer edge of the wafers limits the number of holes formed when bonding the donor substrate of the second semiconductor layer.

According to other, optional features of the present disclosure taken alone or in combination when this is technically possible:
the smoothing heat treatment step E3 is a long thermal annealing carried out at a temperature of between 1050° C. and 1250° C. for a few minutes to a few hours under a pure or mixed hydrogen or argon atmosphere;
the heat treatment step E3 is rapid thermal annealing;
the rapid thermal annealing step E3 is carried out at a temperature of between 1100° C. and 1250° C. for a few seconds to about one hundred seconds, under an atmosphere comprising pure or mixed hydrogen or argon;
the rapid thermal annealing step E1 is carried out at a temperature of between 1100° C. and 1250° C. for a few seconds to about one hundred seconds, under an atmosphere comprising pure or mixed hydrogen or argon;
the thermal oxidation operation of the step E2 is conducted at a temperature of between 800° C. and 1100° C. under an atmosphere comprising oxygen or water vapor for a few minutes to a few hours;
the deoxidation operation of the step E2 is conducted by exposing the surface to be treated to a hydrofluoric acid solution;
the handle substrate and each donor substrate take the form of a wafer of 300 mm in diameter;
the weakened zone in the first donor substrate is formed by implanting hydrogen atoms;
transferring the second semiconductor layer comprises:
forming a weakened zone in the second donor substrate so as to delimit a second semiconductor layer to be transferred,
bonding the second donor substrate to the front side of the semiconductor-on-insulator structure, a second electrically insulating layer being at the interface between the front side of the semiconductor-on-insulator structure and the first donor substrate,
detaching the second donor substrate at the weakened zone, so as to obtain a double semiconductor-on-insulator structure comprising, from the rear side to the front side, the handle substrate, the first electrically insulating layer, the first transferred semiconductor layer, the second electrically insulating layer and the second transferred semiconductor layer;
the weakened zone in the second donor substrate is formed by implanting hydrogen atoms;
the second electrically insulating layer is formed by oxidizing the front side of the first transferred semiconductor layer, so that, when transferring the second semiconductor layer, the first electrically insulating layer is inserted between the first semiconductor layer and the second semiconductor layer, the additional oxidation step being implemented after treating the free surface of the first semiconductor layer;
the second electrically insulating layer is formed by oxidizing a portion of the second donor substrate, so that, when transferring the second semiconductor layer, the first electrically insulating layer is also transferred and is inserted between the first semiconductor layer and the second semiconductor layer;
the first electrically insulating layer is formed by oxidizing the front side of the handle substrate prior to bonding the first donor substrate to the handle substrate so that the first electrically insulating layer is inserted between the handle substrate and the first transferred semiconductor layer;
the first electrically insulating layer is formed by oxidizing a portion of the first donor substrate prior to bonding the first donor substrate to the handle substrate by its oxidized side so that the first electrically insulating layer is inserted between the handle substrate and the first transferred semiconductor layer.

### BRIEF DESCRIPTION OF THE DRAWINGS

Other features and advantages of the present disclosure will emerge from the detailed description that follows, with reference to the accompanying drawings, in which:

FIG. 1 shows a cross-sectional view of the intermediate semiconductor-on-insulator structure obtained following the first layer transfer,

FIG. 2 shows a cross-sectional view of a first layer transfer by a first donor substrate to the front side of the handle substrate, the first electrically insulating layer being formed at the surface of the first donor substrate,

FIG. 3 shows a cross-sectional view of a first layer transfer by a first donor substrate to the front side of the handle substrate, the first electrically insulating layer being formed at the surface of the handle substrate,

FIG. 4 is a diagram showing the sequence of the treatment steps according to the process of the present disclosure,

FIG. 5 shows the final double semiconductor-on-insulator structure obtained following the second layer transfer,

FIG. 6 shows a cross-sectional view of a second monocrystalline semiconductor layer transfer by a second donor substrate, the second electrically insulating layer being formed on the second donor substrate, and

FIG. 7 shows a cross-sectional view of a second monocrystalline semiconductor layer transfer by a second donor substrate, the second electrically insulating layer being formed on the structure of FIG. 2.

For the sake of legibility, the drawings have not necessarily been drawn to scale.

### DETAILED DESCRIPTION

A double semiconductor-on-insulator substrate structure comprises, from the rear side to the front side, a handle substrate, a first buried oxide layer corresponding to a first electrically insulating layer, a first monocrystalline semiconductor layer, a second buried oxide layer corresponding to a second electrically insulating layer and a second monocrystalline semiconductor layer.

The first electrically insulating layer and the first monocrystalline semiconductor layer together form a first semiconductor-on-insulator structure called the lower SOI structure. The second electrically insulating layer and the second monocrystalline semiconductor layer together form a second semiconductor-on-insulator structure called the upper SOI structure.

The present disclosure relates to a process for preparing a double semiconductor-on-insulator structure notably comprising:
preparing the lower SOI structure by transferring firstly a first monocrystalline semiconductor layer according to a SMART CUT™ process,
an intermediate surface treatment process,
preparing the upper SOI structure by transferring secondly a monocrystalline semiconductor layer.

The present disclosure relates more particularly to the intermediate surface treatment process implemented following the SMART CUT™ process for transferring the first monocrystalline semiconductor layer, the SMART CUT™ process and other layer transfer processes also being known.

The surface treatment process of the present disclosure has been optimized so as to minimize the roughness and the defect density of a surface formed after implementing the first SMART CUT™ process so as to improve the quality of bonding during the second layer transfer.

What is meant below by roughness is the maximum peak-to-valley ranges measured by atomic force microscopy (AFM) on outlines of surfaces of between 1×1 μm² and 30×30 μm².

With regard to defect density, it is defined as being the number of particles deposited on the free surface of the wafer and/or the number of structural defects such as holes or scratches that are present at the surface of the wafer. These defects are of various sizes, for example, between 60 nm and several microns. The defects can result from impurities created by locally detaching the irregular edge of the ring (jagged edge) or else from contamination. Defect density is measured with the aid of equipment using a light diffusion technique such as SP2 equipment from KLA-Tencor.

The process also aims to widen the effective bonding zone for the second transferred layer so as to reduce the width of the peripheral ring of the second SOI substrate.

What is called the ring is the peripheral region of an SOI substrate where the monocrystalline semiconductor layer has not been transferred. This ring is due to the fact that the substrates conventionally have a peripheral chamfer of a few millimeters in width, at which the donor substrate cannot be bonded to the receiver substrate. During the SMART CUT™ process, the monocrystalline semiconductor layer of the donor substrate is therefore transferred to the receiver substrate only in the central zone where bonding has taken place. In some cases, isolated zones of the donor substrate can, nevertheless, be transferred to the ring. The ring then does not have a perfectly circular shape, but an irregular jagged edge.

In the case of a double SOI structure, the irregular ring problem therefore occurs twice: when fabricating the first SOI substrate then when fabricating of the second SOI substrate, and therefore has a significant effect on the useful width of the upper semiconductor layer. Thus, if the width of the ring as a result of the first layer transfer is typically between 0.7 mm and 1.5 mm, the width of the “double ring” as a result of the second layer transfer is between 3 mm and 4 mm.

The surface treatment process in accordance with the present disclosure is characterized in that it comprises four successive steps, each step being an already known surface treatment process making it possible to act on one or other of the parameters defined hereinbelow.

However, each of its steps taken individually does not make it possible to achieve the expected performance levels for effective bonding, of good quality so that it is free of defects such as holes at the bonding interface and excessively wide rings, in the context of fabricating a double SOI structure.

The various steps of the intermediate surface treatment process and their impact on the quality of the treated surface are described in detail below. For information purposes, embodiments for preparing the lower and upper SOI structures are also described.

### Preparing the Lower SOI Structure

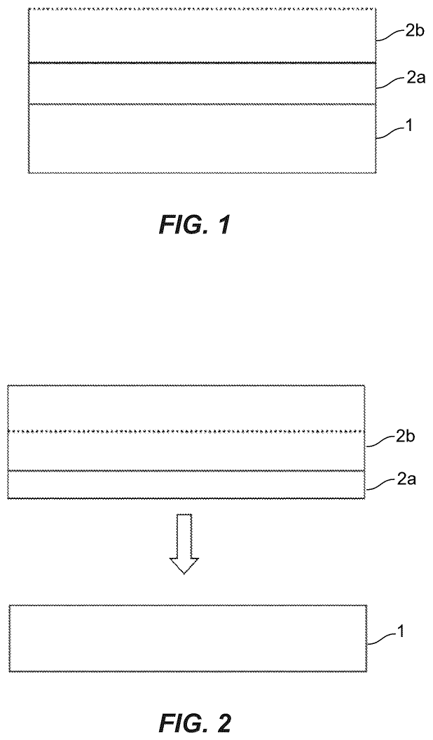

Firstly, the first, lower semiconductor-on-insulator structure or SOI structure is prepared by transferring firstly a monocrystalline semiconductor layer. The structure is shown in FIG. 1. The first transfer is made by a SMART CUT™ process, which comprises the following steps:
providing a first donor substrate of a first monocrystalline semiconductor layer 2b and a handle substrate 1,
forming a weakened zone in the first donor substrate so as to delimit the first semiconductor layer 2b to be transferred,
bonding the first donor substrate to the handle substrate 1, a first electrically insulating layer 2a being at the interface between the handle substrate 1 and the first donor substrate, and
detaching the first donor substrate at the weakened zone.

The handle substrate 1 takes the form of a circular semiconductor wafer, preferably of a wafer of 300 mm in diameter. The handle substrate is, for example, a silicon wafer. The handle substrate is preferably an ultra-flat silicon wafer, which has a chamfer that is less wide and steeper than on conventional wafers.

The width of the edge chamfer of the wafers can be evaluated with the aid of the ZDD148 characteristic, which corresponds to the second derivative of the wafer edge outline at 2 mm from the edge of the wafer, in other words to the inverse of the radius of curvature of this wafer edge. Conventionally, the ZDD148 of silicon wafers of 300 mm in diameter is between −20 and −200 nm/mm². The ZDD148 is measured with the aid of Wafersight equipment from KLA-Tencor. A silicon wafer referred to as ultra-flat has a ZDD148 characteristic between 0 and −20 nm/mm².

Using an ultra-flat silicon wafer makes it possible to reduce the width of the peripheral ring.

The first donor substrate is a monocrystalline semiconductor substrate, for example, a monocrystalline silicon substrate. The first donor substrate takes the form of a wafer, which generally has the same diameter as the handle substrate.

The weakened zone can be created by co-implanting helium atoms and hydrogen atoms in the first donor substrate of the first semiconductor layer. Helium and hydrogen are implanted with energies of between 10 keV and 100 keV and the doses implanted are of between 10¹⁵ atoms per cm² and 10¹⁷ atoms per cm². Alternatively, the weakened zone is preferably created by implanting hydrogen atoms. Co-implanting helium and hydrogen atoms has the advantage of making it possible for the donor substrate to break more cleanly along the weakened zone, which results in lower roughness of the transferred semiconductor layer, of the order of 50 or 60 Å RMS when it is measured by 30×30 μm² AFM, but also in the appearance of the jagged edge phenomenon. The thicker the transferred semiconductor layer, the more pronounced this phenomenon is. Implanting only hydrogen atoms has the advantage of eliminating the jagged edge phenomenon but does, on the other hand, impart greater roughness to the transferred semiconductor layer. The roughness measured by 30×30 μm² AFM is, in this case, of the order of 80 Å RMS. However, the treatment described below makes it possible to obtain a final surface of the first transferred semiconductor layer, which is smooth enough to make it possible to form the second SOI substrate. Consequently, in view of the advantage presented in terms of limiting the jagged edge, implanting only hydrogen atoms will be preferred to co-implanting helium and hydrogen atoms.

The detachment along the weakened zone can be triggered by a mechanical action, a contribution of thermal energy, optionally in combination, or any other suitable means.

According to an embodiment shown in FIG. 2, the first electrically insulating layer 2a is formed on the first donor substrate prior to forming the weakened zone within the first donor substrate by implanting atoms through the first electrically insulating layer 2a. The first donor substrate is bonded to the handle substrate 1 by the electrically insulating side of the first donor substrate so that the first electrically insulating layer 2a is transferred at the same time as the first semiconductor layer 2b and is inserted between the handle substrate 1 and the first transferred semiconductor layer 2b. The first electrically insulating layer 2a is formed, for example, by oxidizing the front side of the first donor substrate, so that, if the first donor substrate is a silicon substrate, the first electrically insulating layer 2a is a silicon oxide layer.

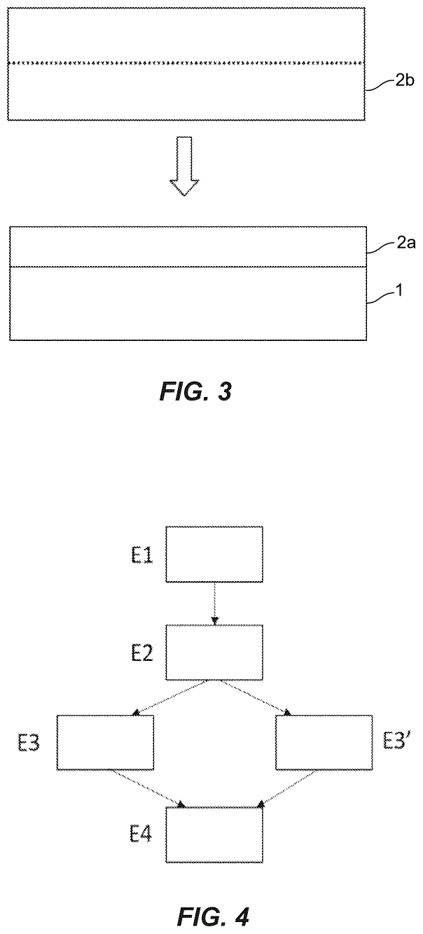

According to an alternative embodiment shown in FIG. 3, the first electrically insulating layer 2a is formed on the front side of the handle substrate 1 prior to bonding the first donor substrate to the handle substrate so that the first electrically insulating layer 2a is inserted between the handle substrate 1 and the first transferred semiconductor layer 2b. The first electrically insulating layer 2a is formed, for example, by oxidizing the front side of the handle substrate 1, so that, if the handle substrate 1 is a silicon substrate, the first electrically insulating layer 2a is a silicon oxide layer.

The front side of the lower SOI structure formed when detaching the first donor substrate along the weakened zone has a roughness and a defect density, which are linked to the quality of implantation of the atomic species within the first donor substrate when implementing the first SMART CUT™ process. As mentioned hereinabove, the roughness may be relatively great, of the order of 50 Å RMS to 80 Å RMS according to the species implanted.

During the second layer transfer for preparing the upper SOI structure, the particular defect density and the surface roughness may lead, at the moment of bonding the second donor substrate, to holes or defects forming. By way of example, a roughness of above 5 Å RMS generates a hole density of the order of several holes per cm².

The holes can cause the devices that will be fabricated from the SOI substrate having the holes to malfunction. Furthermore, the holes are distributed inhomogeneously over the substrate. This inhomogeneity of the defects causes high variability in behavior between the various devices resulting from the same substrate.

Thus, devices produced on portions of the substrate comprising a high hole density will not be operational, or they will possess high variability in behavior, this not being acceptable for a manufacturer of microelectronic devices, notably photonic devices.

Furthermore, the wafer of the handle substrate 1 and the wafer of the first donor substrate do not have an edge that is perpendicular to the surface, but have a chamfer or “edge roll-off.” The first donor substrate is therefore not bonded to the handle substrate over the whole surface of the substrates as far as their edge but only as far as the chamfer, so that the transferred portion of the donor substrate does not extend over the whole surface of the handle substrate. The peripheral ring is delimited on the outside by the edge of the receiver substrate and on the inside by the edge of the transferred layer. For a 300 mm wafer, the peripheral ring CP typically has a width of between 0.7 mm and 1.5 mm with respect to the edge of the wafer.

In reality, as has been mentioned previously, the ring often has an irregular shape (a jagged edge) because of a transitional zone where bonding has not taken place correctly. The transitional zone represents a potential source of defect density: specifically, portions of the zone can detach and be deposited on the surface of the SOI. During the second layer transfer for preparing the upper SOI structure, such a surface finish can also lead to a large number of holes or defects forming and to a width of the double ring, which is much greater than that of the ring resulting from the first layer transfer, of the order of 3 to 4 mm. Such widths are not acceptable, notably for an application in photonics, which requires it to be possible to fabricate chips as far as 3 mm from the edge of the silicon wafers.

The process making it possible to achieve the expected performance levels is described below.

### Surface Treatment Prior to the Second Layer Transfer

The front side of the first semiconductor layer is formed when the first donor substrate is detached along the weakened zone as a result of the Smart Cut™ process. The present disclosure relates to a process for treating the surface. The treatment process in accordance with the present disclosure aims not only to reduce the roughness and the defect density of the surface, but also to reduce the width of the peripheral ring, thus improving the quality of bonding of the second donor substrate.

Treating the free surface of the first semiconductor layer 2b and/or the second semiconductor layer according to the present disclosure involves successively implementing the following steps, shown in the diagram of FIG. 4:
(E1) rapid thermal annealing,
(E2) an oxidation/deoxidation sequence,
(E3) long thermal annealing, known by a person skilled in the art as batch annealing.
(E4) chemical-mechanical polishing.

Alternatively, the long thermal annealing step (E3) can be replaced by a rapid thermal annealing step (E3′).

By “rapid thermal annealing,” what is meant is annealing for a period of a few seconds or a few tens of seconds, under controlled atmosphere. Such annealing is commonly designated by the acronym RTA. The rapid thermal annealing (E1) is carried out at a temperature of between 1100° C. and 1250° C. for 1 s to 90 s. The rapid thermal annealing (E1) is carried out under an atmosphere comprising a mixture of argon and hydrogen or an atmosphere of pure argon.

The rapid thermal annealing makes it possible to reinforce the bonding interface between the handle substrate and the transferred semiconductor layer. It also makes it possible to smooth the surface of the transferred semiconductor layer, by causing the atoms that are present at the surface to be reorganized, and also makes it possible to restore the crystal lattice, which may have been disrupted by the implantation. However, it is not enough for achieving the level of roughness required to make it possible to bond the second donor substrate then to transfer a semiconductor layer of the second donor substrate to the first SOI.

The following oxidation/deoxidation step (E2) must be understood to be a sequence comprising the succession of the following operations:
a thermal oxidation operation (E2a),
a chemical deoxidation operation (E2b).

The oxidation operation (E2a) may be carried out, for example, by heating the structure at a temperature of between 800° C. and 1100° C. for a few minutes to a few hours under an oxidizing atmosphere, for example, of water vapor (wet oxidation) or of only oxygen (dry oxidation). During this oxidation, both sides of the first SOI are oxidized. The deoxidation operation (E2b) may, for example, be carried out by exposing the front side of the structure to a hydrofluoric (HF) acid solution for a few seconds to a few minutes in order to remove the oxide layer formed on the front side, without removing the oxide layer that is present on the rear side of the structure.

This oxidation/deoxidation step consumes, by oxidation then elimination, a silicon surface portion. Consuming surface silicon makes it possible not only to adjust the thickness of the semiconductor layer, but also to eliminate defects that appeared after the layer transfer by SMART CUT™, at the surface of the transferred layer.

Long thermal annealing or batch annealing corresponds to thermal annealing for a period of the order of a few minutes to a few hours, generally above 15 minutes, advantageously carried out in a furnace under a controlled atmosphere. Using the furnace makes it possible to treat a plurality of substrates at the same time.

The thermal annealing (E3) is carried out at a temperature of between 1050° C. and 1250° C. for a few minutes to a few hours under an inert atmosphere, for example, under a pure or mixed hydrogen or argon atmosphere.

The thermal annealing (E3) makes it possible to smooth the surface of the transferred semiconductor layer and therefore to decrease the roughness thereof.

The surface treatment process in accordance with the present disclosure finally comprises a last, chemical-mechanical polishing step (E4).

Over the course of the chemical-mechanical polishing or CMP, the surface to be polished is modified with the aid of a chemical agent, for example, a suspension of colloidal silica particles in a base liquid, and the modified surface is removed by mechanical abrasion. The speed of rotation and pressure used during the CMP step (E4) are optimized so as to uniformly remove material from the surface of the transferred semiconductor layer or the second electrically insulating layer, without however degrading the finish of the surface, notably without increasing the roughness thereof.

Specifically, this chemical-mechanical polishing makes it possible to remove the surface particles. In addition, in so far as this polishing is carried out as far as the edge of the substrate, it also makes it possible to gradually reduce the irregularities in the thickness of the first SOI as far as the wafer edge at the ring of the first SOI, this making possible a second bonding closer to the wafer edge. Thus, the width of the ring resulting from the second transfer by SMART CUT™ is reduced.

Alternatively, the rapid thermal annealing (E3′) is carried out at a temperature of between 1100° C. and 1250° C. for a few seconds to about one hundred seconds, for example, under an atmosphere comprising argon or hydrogen, alone or mixed.

### Preparing the Upper SOI Structure

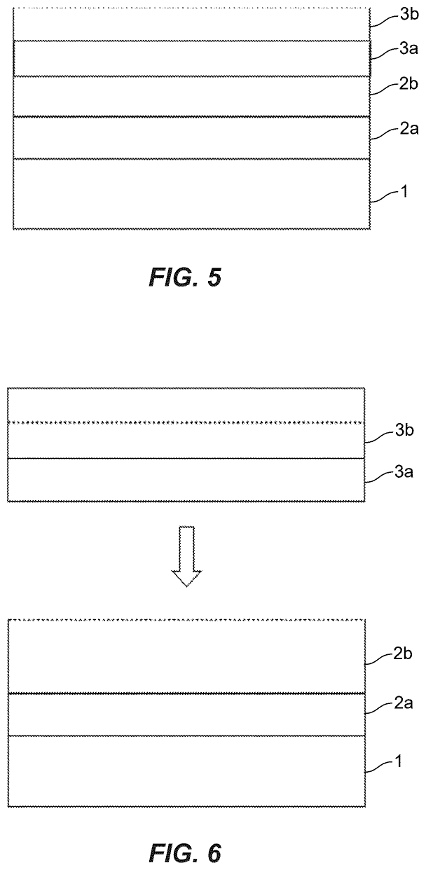

With reference to FIG. 5, the second, upper semiconductor-on-insulator structure or SOI structure is formed on the lower SOI structure by transferring secondly a second monocrystalline semiconductor layer 3b resulting from the second donor substrate, to the front face of the first semiconductor-on-insulator structure, a second electrically insulating layer 3a being at the interface between the first transferred semiconductor layer and the second donor substrate.

The second donor substrate is a monocrystalline semiconductor substrate, for example, a monocrystalline silicon substrate. The second donor substrate takes the form of a circular wafer, which generally has the same diameter as the handle substrate.

According to one embodiment, the second layer transfer is carried out according to a second SMART CUT™ process comprising:
forming a weakened zone in the second donor substrate so as to delimit a second semiconductor layer to be transferred 3b,
bonding the second donor substrate to the front side of the semiconductor-on-insulator structure, a second electrically insulating layer 3a being at the interface between the front side of the semiconductor-on-insulator structure and the first donor substrate,
detaching the second donor substrate at the weakened zone, so as to obtain a double semiconductor-on-insulator structure as shown in FIG. 5.

As for the first donor substrate, the weakened zone within the second donor substrate can be created by co-implanting helium atoms and hydrogen atoms in the second donor substrate of the second semiconductor layer. Alternatively, the weakened zone is created by implanting hydrogen atoms.

As an alternative to the SMART CUT™ process, the second layer transfer can be carried out by thinning the second donor substrate by the side thereof, which is opposite the side bonded to the second electrically insulating layer until the thickness desired for the second semiconductor layer 3b is obtained.

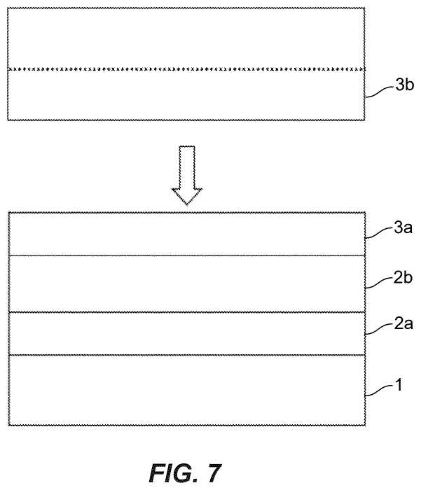

According to an embodiment shown in FIG. 6, the second electrically insulating layer 3a is formed on the second donor substrate, so that, when transferring the second semiconductor layer 3b, the second electrically insulating layer 3a is also transferred and is inserted between the first semiconductor layer 2b and the second semiconductor layer 3b. The second electrically insulating layer 3a is prepared, for example, by oxidizing the second donor substrate, so that, if the second donor substrate is a silicon substrate, the second electrically insulating layer 3a is a silicon oxide layer.

In the embodiment where the second layer transfer is carried out according to a second SMART CUT™ process, the second electrically insulating layer 3a is preferably formed on the second donor substrate prior to the weakened zone being formed within the second donor substrate by implanting atoms through the second electrically insulating layer 3a.

According to an alternative embodiment shown in FIG. 7, the second electrically insulating layer 3a is formed on the first semiconductor layer 2b so that, when transferring the second semiconductor layer 3b, the second electrically insulating layer 3a is inserted between the first semiconductor layer 2b and the second semiconductor layer 3b. The second electrically insulating layer 3a is, for example, prepared by oxidizing the front side of the first transferred semiconductor layer 2b, so that, if the first donor substrate is a silicon substrate, the second electrically insulating layer 3a is a silicon oxide layer. The additional step of forming the second electrically insulating layer 3a is implemented after treating the free surface of the first semiconductor layer 2b. Alternatively, the steps (E1), (E2) and (E3) of the process are implemented on the free surface of the first transferred semiconductor layer 2b before the step of forming the second electrically insulating layer 3a and the step (E4) can be implemented before and after the step of forming the second electrically insulating layer 3a, on the surface of the first transferred semiconductor layer 2b and on the surface of the second electrically insulating layer 3a, respectively.

The free surface of the second electrically insulating layer 3a can advantageously be cleaned once or several times prior to transferring secondly a second monocrystalline semiconductor layer 3b.

By way of example, implementing the surface treatment process in accordance with the present disclosure, which notably combines thermal smoothing and a CMP step, coupled with using an “ultra-flat” handle substrate, makes it possible to obtain an SOI structure that has a very small number of, or even no, holes and a double ring width of under 3 mm.

Optionally, a treatment of the free surface of the second semiconductor layer 3b can also be undertaken in order to reduce the defects in this layer and smooth the surface thereof in order to obtain the properties required for the subsequent applications of the layer (fabricating electronic components, epitaxy, etc.) These treatments are known to a person skilled in the art and include, for example, rapid thermal annealing.

1. A method of fabricating a double semiconductor-on-insulator structure, comprising the following steps:
providing a first donor substrate and a handle substrate;
forming a weakened zone in the first donor substrate so as to delimit a first semiconductor layer to be transferred;
bonding the first donor substrate to the handle substrate, a first electrically insulating layer being at an interface between the handle substrate and the first donor substrate, and detaching the first donor substrate at the weakened zone, so as to obtain a semiconductor-on-insulator structure comprising, from a rear side to a front side, the handle substrate, the first electrically insulating layer and the first transferred semiconductor layer;
treating a free surface of the first transferred semiconductor layer;
providing a second donor substrate of a second semiconductor layer to be transferred;
transferring the second semiconductor layer to the front side of the semiconductor-on-insulator structure, a second electrically insulating layer being at the interface between the first transferred semiconductor layer and the second donor substrate, wherein treating the surface of the first transferred semiconductor layer comprises the following successive steps:
rapid thermal annealing,
a sequence including a thermal oxidation followed by a deoxidation,
a smoothing heat treatment at a temperature of above 1000° C. in a non-oxidizing atmosphere, and
chemical-mechanical polishing.

2. The method of claim 1, wherein the smoothing heat treatment step is a long thermal annealing carried out at a temperature of between 1050° C. and 1250° C. for a few minutes to a few hours under a pure or mixed hydrogen or argon atmosphere.

3. The method of claim 1, wherein the smoothing heat treatment step is a rapid thermal annealing.

4. The method of claim 3, wherein the rapid thermal annealing step of the smoothing heat treatment step is carried out at a temperature of between 1100° C. and 1250° C. for a few seconds to about one hundred seconds, under an atmosphere comprising pure or mixed hydrogen or argon.

5. The method of claim 1, wherein the rapid thermal annealing step is carried out at a temperature of between 1100° C. and 1250° C. for a few seconds to about one hundred seconds, under an atmosphere comprising pure or mixed hydrogen or argon.

6. The method of claim 1, wherein the thermal oxidation operation of the step is conducted at a temperature of between 800° C. and 1100° C. under an atmosphere comprising oxygen or water vapor for a few minutes to a few hours.

7. The method of claim 1, wherein the deoxidation operation of the step is conducted by exposing the surface to be treated to a hydrofluoric acid solution.

8. The method of claim 1, wherein each of the handle substrate and each donor substrate respectively comprise a wafer having a diameter of 300 mm.

9. The method of claim 1, wherein the weakened zone in the first donor substrate is formed by implanting hydrogen atoms.

10. The method of claim 1, wherein transferring the second semiconductor layer comprises:
forming a weakened zone in the second donor substrate so as to delimit a second semiconductor layer to be transferred;
bonding the second donor substrate to the front side of the semiconductor-on-insulator structure, a second electrically insulating layer being at the interface between the front side of the semiconductor-on-insulator structure and the first donor substrate; and
detaching the second donor substrate at the weakened zone to obtain a double semiconductor-on-insulator structure comprising, from the rear side to the front side, the handle substrate, the first electrically insulating layer, the first transferred semiconductor layer, the second electrically insulating layer and the second transferred semiconductor layer.

11. The method of claim 10, wherein the weakened zone in the second donor substrate is formed by implanting hydrogen atoms.

12. The method of claim 1, wherein the second electrically insulating layer is formed by oxidizing the front side of the first transferred semiconductor layer, so that, when transferring the second semiconductor layer, the first electrically insulating layer is inserted between the first semiconductor layer and the second semiconductor layer, the additional thermal oxidation step being implemented after treating the free surface of the first semiconductor layer.

13. The method of claim 1, wherein the second electrically insulating layer is formed by oxidizing a portion of the second donor substrate, so that, when transferring the second semiconductor layer, the first electrically insulating layer is also transferred and is inserted between the first semiconductor layer and the second semiconductor layer.

14. The method of claim 1, wherein the first electrically insulating layer is formed by oxidizing the front side of the handle substrate prior to bonding the first donor substrate to the handle substrate so that the first electrically insulating layer is inserted between the handle substrate and the first transferred semiconductor layer.

15. The method of claim 1, wherein the first electrically insulating layer is formed by oxidizing a portion of the first donor substrate prior to bonding the first donor substrate to the handle substrate by its oxidized side so that the first electrically insulating layer is inserted between the handle substrate and the first transferred semiconductor layer.

16. A method of fabricating a double semiconductor-on-insulator structure, comprising:
providing a semiconductor-on-insulator structure comprising, from a rear side to a front side, a handle substrate, a first electrically insulating layer, and a first transferred semiconductor layer;
treating a free surface of the first transferred semiconductor layer by performing the following successive steps:
rapid thermal annealing of at least the free surface of the semiconductor-on-insulator structure,
thermal oxidation followed by deoxidation of the free surface,
performing a smoothing heat treatment of the free surface at a temperature of above 1000° C. in a non-oxidizing atmosphere, and
chemical-mechanical polishing of the free surface; and
transferring a second semiconductor layer to the front side of the semiconductor-on-insulator structure, a second electrically insulating layer being at the interface between the first transferred semiconductor layer and the second semiconductor layer.

17. The method of claim 16, wherein the smoothing heat treatment step is a long thermal annealing carried out at a temperature of between 1050° C. and 1250° C. for a few minutes to a few hours under a pure or mixed hydrogen or argon atmosphere.

18. The method of claim 16, wherein the smoothing heat treatment step is a rapid thermal annealing.

19. The method of claim 18, wherein the rapid thermal annealing of the smoothing heat treatment step is carried out at a temperature of between 1100° C. and 1250° C. for a few seconds to about one hundred seconds, under an atmosphere comprising pure or mixed hydrogen or argon.

20. The method of claim 16, wherein the rapid thermal annealing step is carried out at a temperature of between 1100° C. and 1250° C. for a few seconds to about one hundred seconds, under an atmosphere comprising pure or mixed hydrogen or argon.
